(19) United States
(12) Patent Application Publication
(10) Pub. No.: US 2022/0140172 A1
(43) Pub. Date: May 5, 2022

(54) LIGHT SENSING DEVICE PACKAGING STRUCTURE AND PACKAGING METHOD THEREOF

(71) Applicant: SENSORTEK TECHNOLOGY CORP., Zhubei City (TW)

(72) Inventors: WEN-CHIEH TSOU, ZHUBEI CITY (TW); YI-HUA CHANG, ZHUBEI CITY (TW)

(21) Appl. No.: 17/212,362

(22) Filed: Mar. 25, 2021

Related U.S. Application Data
(60) Provisional application No. 62/994,756, filed on Mar. 25, 2020.

(51) Int. Cl. H01L 31/12; H01L 27/146; H01L 33/62; H01L 23/552

(52) U.S. Cl. CPC H01L 31/125; H01L 27/14636; H01L 27/14687; H01L 23/552; H01L 33/62

(57) ABSTRACT

A light sensing packaging structure and a packaging method thereof is provided, wherein the light sensing packaging structure comprises a substrate provided with a through-hole between a light-emitting element and a light-sensing element; and a cover body covered the substrate. The cover body comprises a shielding part and an extended part. The shielding part is mounted between the light-emitting element and the light-sensing element, and provided with a metal bonding layer on a surface towards the substrate. The extended part is provided with a metal side wall connected to the metal bonding layer. The through-hole is covered with a conductive glue, and the metal junction contacts the conductive glue. Hereby, the present application may reduce the size of the light sensing device, provide a stable packaging, reduce the packaging cost and improve the reliability of the light sensing product.

### FIELD OF THE INVENTION

The present invention refers to a light sensing device packaging structure and packaging method, in particular to the light sensing device packaging structure and packaging method that can shield Electromagnetic Interference (EMI).

### BACKGROUND OF THE INVENTION

The light sensing devices performed via light sensing technology are widely used in many applications. For example, the Ambient Light Sensor (ALS) can be used in electronic products to sense the intensity of ambient light for adjusting the brightness of display screen to enhance the using convenience and extend the battery life. The proximity sensor can be used to detect the distance between the user's face and the display screen of electronic device. Therefore, when the proximity sensor is closed to the user's face, the electronic device can turn off the display screen and the touch function, preventing the user's face from accidentally touching the display screen during a call that would interrupt the conversation.

The proximity sensor and ALS are generally integrated into a single package structure in the perspective that they can be applied in small, portable electronic devices such as the mobile phones. Both the proximity sensor and ALS need the light-sensing elements and the proximity sensors normally also need the light-emitting elements (such as the infrared emitters) too. In order to prevent the light generated by the light-emitting element from interfering with the light-sensing element, in the conventional method it keeps a certain distance between the light-emitting element and the light-sensing element to avoid crosstalk. However, this method occupies a larger space of the electronic devices and also consumes more power. In the situation of limited space, the way of avoiding crosstalk is to provide a shielding element between the light-emitting element and the light-sensing element. Typically, the shielding element is added during the chip packaging process.

However, except the light interference made by the light-emitting element, the electromagnetic wave generated by the electromagnetic induction effect will also cause the Electromagnetic Interference (EMI) to the light sensing devices, and further forms noise that decays the accuracy of light sensors. The previous EMI shielding technology is to cover the light sensing element with a metal cover, which relies on an additional metal cover on the light sensing device to shield EMI. However, the metal cover is large in size, taking up space and is not easy to be mounted onto the light sensing device packaging structure; and it is easy to drop off from the packaging structure too. Besides, it needs to mount the metal covers to each of the light sensors one-by-one, which cannot be operated by connecting multiple light sensors together in one lotand the cost is expensive; making the existing light sensors that can shield EMI are less accepted in the cost-intensive consumer electronics market.

Under the trend that the electronic products go on developing toward miniaturization and low power consumption, it is necessary to provide a further improved light sensing device packaging structure and packaging method to reduce the volume of light sensing device packaging structure and provide the function of shielding EMI interfering against signals, in the perspective of enhancing the practicability of light sensors.

### SUMMARY

The purpose of the present invention is to provide a light sensing device packaging structure and packaging method, which equips a through-hole (also called “Via”) between a light emitting element and a light-sensing element; the through-hole (Via) is covered with conductive glue, which allows the metal junction on the cover body to form a stable loop by contacting the conductive glue. Therefore, the light sensing device packaging structure and packaging method expressed in the present invention can reduce the volume of light sensor, provide a stable packaging, reduce the packaging cost and upgrade the product reliability.

The present invention refers to a light sensing device packaging structure, which includes a substrate, a light-emitting element, a light-sensing element and a cover. The substrate is equipped with a through-hole (Via). The light-emitting element and the light-sensing element are equipped in the substrate located at both sides of the through-hole (Via). The cover body covers the substrate and contains a shielding part and an extended part; the shielding part is equipped between the light-emitting element and the light-sensing element and extends toward the substrate; the extended part is connected with the shielding part and surrounds the light-emitting element or the light-sensing element. The surface of the shielding part facing the substrate is equipped with a metal junction; the extended part is equipped with a metal side-wall; the metal side-wall is connected with the metal junction; and the through-hole (Via) is covered with a conductive glue on the surface of the substrate in the direction facing the cover body; the metal junction contacts the conductive glue.

The present invention refers to a packaging method of the light sensing device packaging structure, which includes: A light-emitting element and a light-sensing element equipped on a substrate; with one or more through-holes (Via) equipped between the light-emitting element and the light-sensing element of the substrate; the conductive glue is put on the through-hole (Via) to cover it; a cover made of an opaque material contains a shielding part and an extended part that is connected with the shielding part, the extended part and the shielding part form an accommodating space; a metal junction on a surface of the shielding part away from the extended part that is formed by the electroplating process, and a metal side-wall on the surface of the cover body facing the accommodating space that is formed by the electroplating process, which is connected with the metal junction; and make the metal junctions on the cover body and the substrate contact the conductive glue, the accommodating space is for the light-emitting element or the light-sensing element.

### BRIEF DESCRIPTION OF THE DRAWINGS

FIG. 1: The schematic cross-sectional view of the light sensing device packaging structure in an embodiment of the present invention.

FIG. 2: The partial schematic cross-sectional view of the light sensing device packaging structure in an embodiment of the present invention.

FIG. 3: The schematic diagram of the packaging method of the light sensing device packaging structure, showing the elements equipped in the substrate, in an embodiment of the present invention.

FIG. 4: The schematic diagram of the packaging method of the light sensing device packaging structure, using the transparent material to package the light-emitting element and the light-sensing element, in an embodiment of the present invention.

FIG. 5: The schematic diagram of the packaging method of the light sensing device packaging structure, forming the transparent molding substance and exposing the through-hole (Via) on the surface of the board, in an embodiment of the present invention.

FIG. 6: The schematic diagram of the packaging method of the light sensing device packaging structure, covering the conductive glue on the through-hole (Via), in an embodiment of the present invention.

FIG. 7: The schematic diagram of the packaging method of the light sensing device packaging structure, making the cover body and forming the metal junction and the metal side-wall, in an embodiment of the present invention.

FIG. 8: The schematic diagram of the packaging method of the light sensing device packaging structure, showing the outer appearance after connecting the cover body and the substrate, in an embodiment of the present invention.

### DETAILED DESCRIPTION

Some words in the Invention Description and the Claims are used to indicate the specific elements. However, persons with general knowledge in the technical field of the present invention should understand that the manufacturer may use different names to refer to the same element. Moreover, the descriptions and Claims do not use the name difference as a way to distinguish components, but will take the differences in overall technology of components as the distinction criteria. “Including” mentioned in the entire Invention Description and the Claim items is an “open” term, it should be interpreted as “including but not limited to”. Furthermore, the term “coupling” includes any direct and indirect means of connection. Therefore, if a first device is described to be coupled to a second device, it means that the first device can be directly connected to the second device or indirectly connected to the second device through other devices or other means of connection.

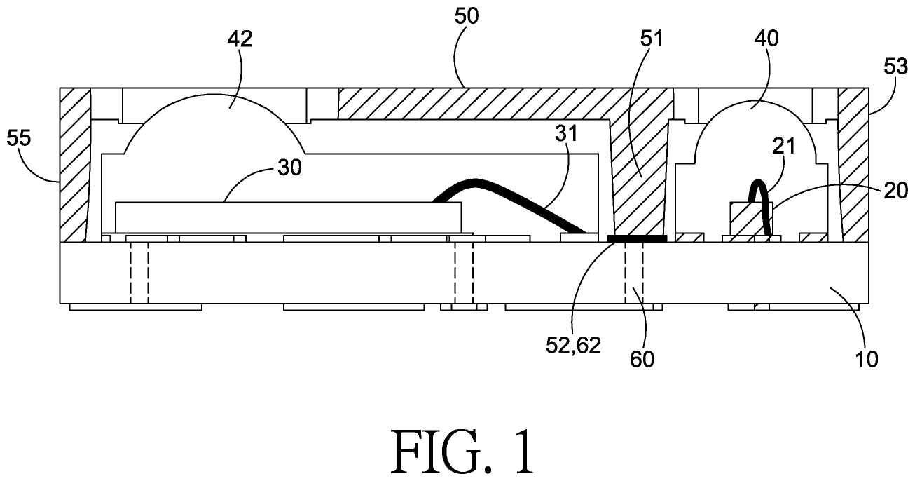

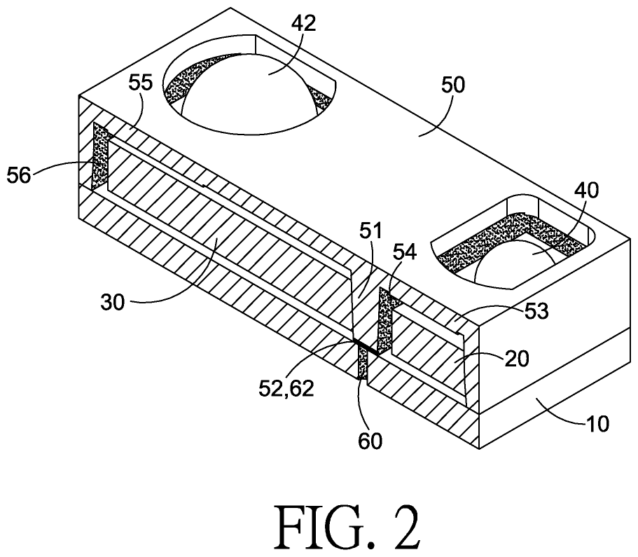

Referring to FIG. 1 and FIG. 2; FIG. 1 is the schematic cross-sectional view of the light sensing device packaging structure in an embodiment of the present invention, FIG. 2 is the partial schematic cross-sectional view of the light sensing device packaging structure in an embodiment of the present invention. The light sensing device packaging structure includes a substrate 10, a light-emitting element 20, a light-sensing element 30, a transparent molding substance 40 and 42 and a cover 50.

The light-emitting element 20 and the light-sensing element 30 is equipped on the substrate 10, the light-emitting element 20 can be connected with the substrate 10 through the conductive wire 21, and the light-sensing element 30 can be connected with the substrate 10 through the conductive wire 31. Yet, except the conventional wiring process, the light-emitting element 20 or the light-sensing element 330 can be connected with substrate 10 through other way and the present invention isn't limited to that only. In an embodiment, the substrate 10 can be a copper-foil substrate, a ceramic substrate, a conductive wire bracket, a resin substrate or a PCB, and the conductive wires 21 and 31 can be gold or copper wire, but not limited to the these materials.

In this embodiment, the light sensing device packaging structure can be integrated with a proximity sensor and/or an ALS. The light-emitting element 20 can be used to generate the emitted light (for example, the infrared ray), the light-sensing element 30 is used to receive the reflective light of the emitted light from the object, enabling the proximity sensor to calculate the distance from the emitted and reflective lights. In addition, the light-sensing element 30 also can be used to receive the ambient light from ambient light sources for the ALS making the light intensity calculation. In this embodiment, the operational circuit of proximity sensor and the ALS is equipped in the area identical to the light-sensing element 30, whereas the light-emitting element 20 is a distance away from this area. In an embodiment, the proximity sensor and the ALS have their own respective light-sensing element; therefore there are a plurality of light-sensing element 30.

The light-emitting element 20 and the conductive wire 21 are sealed in the transparent molding substance 40, the light-sensing element 30 and the conductive wire 31 are sealed in the transparent molding substance 42; the transparent molding substance 40 and 42 can be used to protect the light-emitting element 20 and the light-sensing element 30. The cover body 50 is better made of opaque plastics, and the cover body 50 covers the substrate 10 to block out the unexpected light from accessing the light sensing device packaging structure; the cover body 50 is equipped with openings at the light-accessing locations of the light-emitting element 20 and the light-sensing element 30, having the emitted and reflective lights pass through them. The cover body 50 contains a shielding part 51; this shielding part 51 is equipped between the light-emitting element 20 and the light-sensing element 30 and extends toward the substrate 10, avoiding the light-emitting element 20 from generating light to interfere with the light-sensing element 30 and form the crosstalk. The cover body 50 also contains at least an extended part 53 and 55 that is connected with the shielding part 51; in this embodiment, an extended part 53 of the cover body 50 extends to the right side of the drawing from the shielding part 51 and surrounds the light-emitting element 20; the other extended part 55 of the cover body 50 extends to the left side of the drawing from the shielding part 51 and surrounds the light-sensing element 30.

It shall be noted that the surface of shielding part 51 in the cover body 50 facing the substrate 10 is electroplated with a metal junction 52, and the cover body 50 has at least an electroplated metal side-wall 54 and 56, the metal side-wall 54 and 56 is connected with the metal junction 52. In this embodiment, a metal side-wall 54 in the cover body 50 is equipped on the surface of the shielding part 51 and the extended part 53 facing the light-emitting element 20, which is connected with the metal junction 52 and shields the light-emitting element 20; and the other metal side-wall 56 in the cover body 50 is equipped on the surface of the shielding part 51 and the extended part 55 facing the light-sensing element 30, which is connected with the metal junction 52 and shields the light-sensing element 30. As illustrated above, the cover body 50 is better made of opaque plastics so that the metal junction 52 and metal side-wall 54 and 56 can be formed by the plastic electroplating process.

The substrate 10 is equipped with at least a Via 60, the Via 60 can be the through-hole that passes through the surfaces at both sides of the substrate 10, or the blind hold being exposed to the substrate 10 facing the cover body 50. The Via 60 is better grounded, in addition, a surface of the Via 60 at the substrate 10 facing the cover body 50 is covered with conductive glue 62; the conductive glue 62 can be the conductive silver glue or other conductive glues. The shielding part 51 surface at the cover body 50 facing substrate 10 is equipped with the metal junction 52; the metal junction 52 contacts the conductive glue 62 and is electrically connected with the Via 60.

From the above, the metal junction 52 and the metal side-wall 54 and 56 in the cover body 50 can form a metal mask and the metal junction 52 and the conductive glue 62 are electrically connected with the Via 60 to form a loop and co-build a stable grounding structure. Therefore, the light sensing device packaging structure of this embodiment can effectively shield EMI and block out the spreading of interference by means of the metal junction 52 and the metal side-wall 54 and 56. The larger the area of the metal side-wall 54 and 56 takes, the better the effect of shielding the light-emitting element 20 or the light-sensing element 30 makes and a better EMI shielding effect can be obtained. However, it may increase the manufacturing complexity and material cost, which should be designed according to the needs of users who implement the embodiment of the present invention.

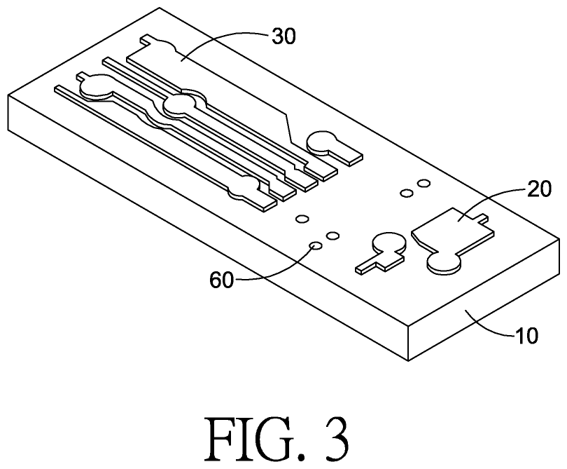

The packaging method of the aforesaid embodiment of the light sensing device packaging structure in the present invention will be described in detail below. Refer to FIG. 3, a substrate 10 is equipped with the light-emitting element 20 and the light-sensing element 30; it equips one or more Via 60 between the light-emitting element 20 and the light-sensing element 30 in the substrate 10; and the Via 60 is grounded.

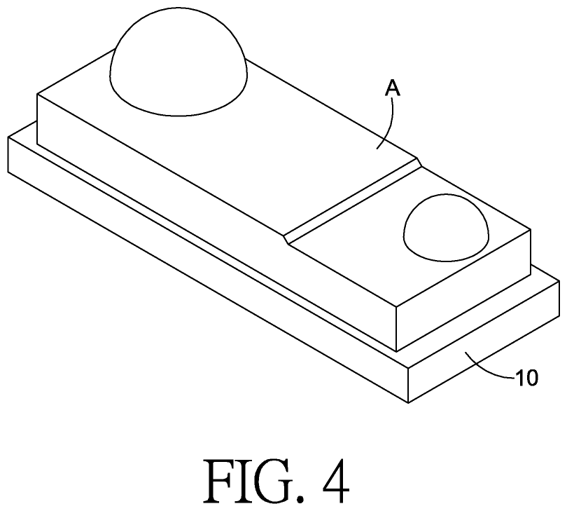

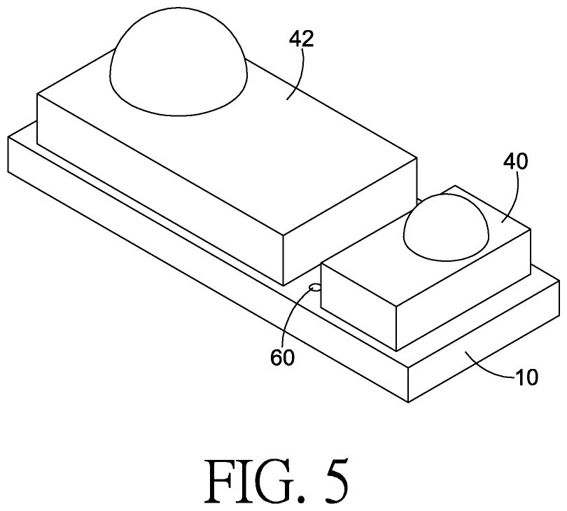

Refer to FIG. 4 and FIG. 5, perform the molding packaging process to the substrate 10 to form the transparent molding substance 40 and 42; seal the light-emitting element 20 into the transparent molding substance 40, seal the light-sensing element 30 into the transparent molding substance 42 and have the Via 60 exposed on the surface of the substrate 10. As shown in FIG. 4, this embodiment uses a transparent material “A” to directly package and enclose the light-emitting element 20 and the light-sensing element 30. As shown in FIG. 5, remove part of the transparent material “A” through the subsequent cutting, grinding and itching process to form the transparent molding substance 40 and 42 and have the Via 60 exposed on the surface of the substrate 10. Yet, in part of the embodiments of the present invention, it can cover the Via 60 in the substrate 10 through a mold, and inject the liquid transparent glue (for example, resin) into the mold; after the glue is solidified, it forms the transparent molding substance 40 and 42 directly; then, remove the mold and make the Via 60 exposed to the surface of substrate 10.

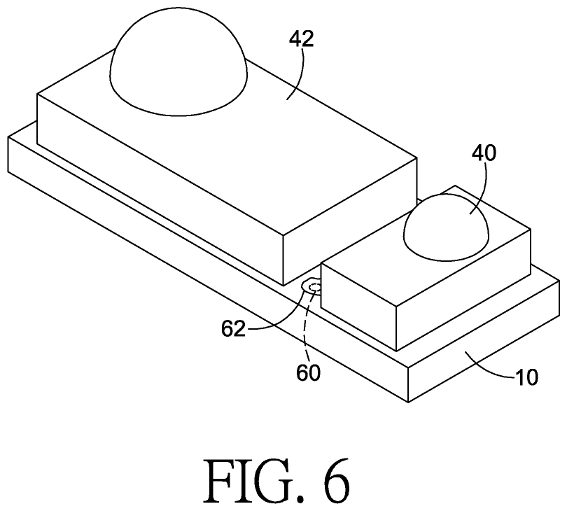

Refer to FIG. 6; cover a conductive glue 62 on the Via 60. The conductive glue 62 can be the conductive silver glue or other conductive glues.

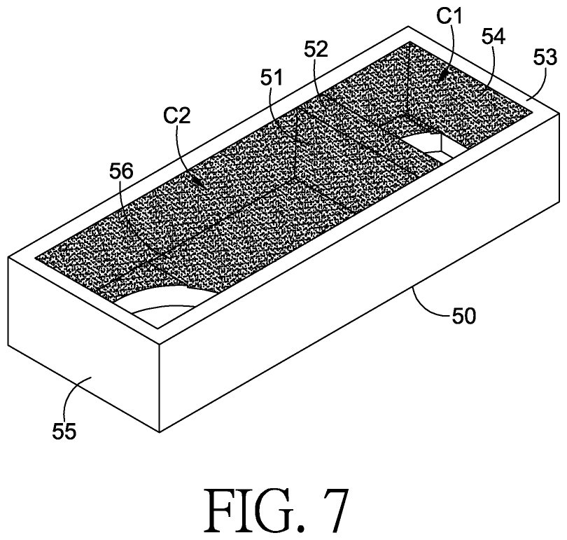

Refer to FIG. 7; use opaque material to make a cover 50, the cover body 50 contains a shielding part 51 and at least an extended part 53 and 55 that is connected with the shielding part 51. In this embodiment, an extended part 53 in the cover body 50 extends from the shielding part 51 to the right side of the drawing, forming the first accommodating space “C1” along with the shielding part 5; the other extended part 55 in the cover body 50 extends from the shielding part 51 to the left side of the drawing, forming the second accommodating space “C2” along with the shielding part 51. Electroplate a surface of shielding part 51 away from the extended part 53 and 55 to form a metal junction 52, and electroplate the surface of the cover body 50 facing the first accommodating space “C1” or the second accommodating space “C2” to form a metal Side-Wall 54 and 56. In this embodiment, the surface of the cover body 50 facing the first accommodating space “C1” has formed a metal side-wall 54; the metal side-wall 54 is equipped at the shielding part 51 and the extended part 53 connected with the metal junction 52 to shield the first accommodating space “C1”; and the surface of the cover body 50 facing the second accommodating space “C2” has formed the other metal side-wall 56; the metal side-wall 56 is equipped at the shielding part 51 and the extended part 55 connected with the metal junction 52 to shield the second accommodating space “C2”. The cover body 50 is better made of opaque plastics, and thus the metal junction 52 and metal side-wall 54 and 56 can be formed by plastic electroplating process.

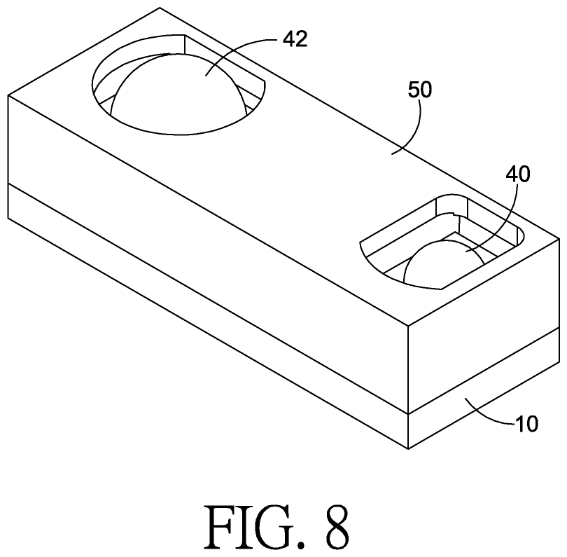

Refer to FIG. 8; make the cover body 50 be connected with the substrate 10; the first accommodating space “C1” can accommodate the transparent molding substance 40 and the sealed light-emitting element 20; the second accommodating space “C2” can accommodate the transparent molding substance 42 and the sealed light-sensing element 30. The surface of shielding part 51 in the cover body 50 facing the substrate 10 is equipped with the metal junction 52; the metal junction 52 contacts the conductive glue 62 and is electrically connected with the Via 60.

Using the light sensor packaging method stated in the embodiment of the present invention to package the light sensing device packaging structure cannot only provide a metal mask to effectively block out EMI and the spreading of interference, it also doesn't need the metal cover used in the conventional art. On the contrary, as mentioned above, in the embodiment of the present invention, the cover body can be made of opaque plastics with smaller volume meeting the needs of miniaturization of electronic products. Moreover, the cover body made of plastics is easier to be mounted on the light sensing device packaging structure than the metal cover, and it is not as easy to drop off from the packaging structure as the metal cover does. The cover body made of opaque plastic can be easily shaped, forming a firm fit with the substrate without drop-off. Besides, unlike the metal covers that need to be one-by-one mounted separately, the connection of covers and substrate can be operated per sheet that can greatly reduce the production cost of the light sensing device packaging structure.

More importantly, the present invention can ensure that the metal junction of the cover body and the through-hole (Via) will form a stable grounding loop by covering the conductive glue on the through-hole (Via). In contrast, even if the metal cover used in the conventional art does not have the drop-off problem, as long as there is a slight assembly deviation or displacement, it may not be able to form a grounding loop, and the function of shielding EMI may be completely invalid. The packaging of light sensing device packaging structure produced by using the packaging method stated in the embodiment of the present invention is obviously more reliable.

1. A light sensing device packaging structure, including:
a substrate, equipped with a through-hole;
a light-emitting element and a light-sensing element, disposed on the substrate and located at both sides of the through-hole; and
a cover body, covered the substrate, the cover body comprising a shielding part and an extended part; the shielding part disposed between the light-emitting element and the light-sensing element and extended to the direction facing the substrate, the extended part connected with the shielding part and surrounded the light-emitting element or the light-sensing element;
wherein a surface of the shielding part facing the substrate is equipped with a metal junction; the extended part is equipped with a metal side-wall; the metal side-wall is connected with the metal junction; a surface of the through-hole on the substrate facing the cover body is covered with the conductive glue; the metal junction contacts the conductive glue.

2. The light sensing device packaging structure of claim 1, wherein the cover body is made of the opaque plastics; the metal junction and the metal side-wall are formed by the plastic electroplating process.

3. The light sensing device packaging structure of claim 1, wherein the through-hole is connected to ground, which makes the metal side-wall, the metal junction, the conductive glue and the through-hole be electrically connected to form a grounding loop.

4. The light sensing device packaging structure of claim 1, wherein the light-emitting element is sealed in a transparent molding substance, the light-sensing element is sealed in the other transparent molding substance.

5. The light sensing device packaging structure of claim 1, wherein the cover body has openings located at the positions corresponding to light emitting and light entering locations of the light-emitting element and the light-sensing element.

6. The light sensing device packaging structure of claim 1, wherein the extended part is extended from the shielding part and surrounded the light-sensing element; the metal side-wall shields the light-sensing element.

7. The light sensing device packaging structure of claim 6, wherein the cover body further comprises the other extended part, connected with the shielding part and surrounded the light-emitting element, the extended part further equipped with the other metal side-wall connected with the metal junction and shielded the light-emitting element

8. A light sensor packaging method, including:
equipping a light-emitting element and a light-sensing element on a substrate; equipping one or more through-holes between the light-emitting element and light-sensing element of the substrate;
covering the conductive glue on the through-hole;
using opaque material to make a cover, the cover body contains a shielding part and an extended part that connects the shielding part; the extended part and the shielding part form an accommodating space;
forming a metal junction by electroplating process on a surface of the shielding part away from the extended part, and forming a metal side-wall by electroplating process on the surface of the cover body facing the accommodating space; the metal side-wall is connected with the metal junction; and
arranging the cover body and the substrate and making the metal junction contact the conductive glue; the accommodating space is for accommodating the light-emitting element or the light-sensing element.

9. The light sensor packaging method of claim 8, wherein the cover body is made of the opaque plastics, the metal junction and the metal side-wall are formed by electroplating process.

10. The light sensor packaging method of claim 8, wherein it also contains the process of grounding the through-hole, making the metal side-wall, metal junction, conductive glue and through-hole be electrically connected to form a grounding loop.

11. The light sensor packaging method of claim 8, wherein after the substrate is equipped with the light-emitting element and the light-sensing element, it also seals the light-emitting element into a transparent molding substance, and seals the light-sensing element into the other transparent molding substance; and it makes the through-hole be exposed to the substrate surface.

12. The light sensor packaging method of claim 11, wherein it uses a transparent material to cover the light-emitting element and light-sensing element, and then removes part of the transparent material to form the two transparent molding substances and makes the through-hole be exposed to the substrate surface.

13. The light sensor packaging method of claim 11, wherein it covers the through-hole in the substrate through a mold, and injects the liquid transparent glue into the mold; after the glue is solidified, it forms the two transparent molding substances; then, remove the mold and make the through-hole be exposed to the surface of the substrate.

14. The light sensor packaging method of claim 8, wherein the accommodating space accommodates the light-sensing element; and the metal side-wall shields the light-sensing element.

15. The light sensor packaging method of claim 8, wherein the cover body includes the other extended part that is connected with the shielding part; the other extended part and the shielding part form the other accommodating space; it also includes that the surface of the cover body facing the other accommodating space forms the other metal side-wall by electroplating process; the other metal side-wall is connected with the metal junction; the other accommodating space accommodates the light-emitting element; and the other metal side-wall shields the light-emitting element.
